(19) United States
(12) Patent Application Publication
(10) Pub. No.: US 2012/0049922 A1
(43) Pub. Date: Mar. 1, 2012

(54) TOTAL ENERGY LIMITING AND CONTROLLING DEVICE, AND TOTAL ELECTRIC POWER LIMITING AND CONTROLLING DEVICE AND METHOD

(75) Inventors: Masato Tanaka, Tokyo (JP); Mayumi Miura, Tokyo (JP)

(73) Assignee: YAMATAKE CORPORATION, Tokyo (JP)

(21) Appl. No.: 13/207,743

(22) Filed: Aug. 11, 2011

(30) Foreign Application Priority Data
Aug. 25, 2010 (JP) 2010-188241

(51) Int. Cl. H03L 5/00

(52) U.S. Cl. 327/309

(57) ABSTRACT

A total electric power limiting and controlling device has a total allocated electric power inputting portion receiving information for the total allocated electric power specifying the amount of electric power used by heaters in multiple controlled loops. An electric power value obtaining portion obtains an electric power consumption value for the individual loops. Electric power limiting portions calculate an electric power surplus of the individual loops, from the electric power consumption values, and calculates an operating quantity output upper limit value for each of the loops based on the ratios of the electric power surpluses of the individual loops relative to the total electric power surplus and on the total allocated electric power. A controlling portion, provided for each loop, calculates the operating quantity, performs an upper limit process on the operating quantity, and outputs the operating quantity, after the upper limit process, to the heater of the corresponding loop.

### CROSS REFERENCE TO RELATED APPLICATIONS

The present application claims priority under 35 U.S.C. §119 to Japanese Patent Application No. 2010-188241, filed Aug. 25, 2010, which is incorporated herein by reference.

### FIELD OF TECHNOLOGY

The present invention relates to a controlling device and controlling method for a multi-loop control system provided with a plurality of controlled loops, and, in particular, relates to a total energy limiting and controlling device and total electric power limiting and controlling device and method for performing control so that the quantity of energy used (for example, the quantity of electrical power used) in a steady state does not exceed a prescribed value that has been specified, and so that, insofar as is possible, external noise limiting performance is not lost.

### BACKGROUND OF THE INVENTION

Given, for example, legislation arising from the global warming problem, there are demands for strengthened control of the quantity of energy used in factories and manufacturing lines. Because heat-producing equipment and air-conditioning equipment are facilities equipment that can consume a particularly large quantity of electricity, often the upper limit for the quantity of energy consumed is controlled so as to be kept lower than the maximum value in conventional equipment. For example, in facilities equipment that runs on electric power, the operations are performed in particular so that the quantity of electricity used will be within specific limitations prescribed by an electric power demand controlling system.

In particular, there have been proposals for methods, such as described below, for limiting the total quantity of electric power that is supplied simultaneously at the time of startup in heat-producing equipment that is provided with a plurality of electric heaters (when heating up simultaneously the temperature in multiple areas wherein electric heaters are installed).

In the reflow equipment disclosed in Japanese Patent 2885047 (“JP '047”), in order to reduce the quantity of electric current consumed at the time of startup, the startup time bands are offsetted from each other so that one heater is started up after the thermal saturation of the vicinity of the previous heater.

In the semiconductor wafer processing equipment disclosed in Japanese Unexamined Patent Application Publication H11-126743 (“JP '743”), electric power is provided while providing timing differences for the individual heaters, so as to not consume large quantities of electric power all at once at the time of equipment startup.

In the substrate processing device disclosed in Japanese Unexamined Patent Application Publication H11-204412 (“JP '412”), in order to reduce the maximum electric power that is provided at a given time from an electric power providing portion, a specific startup sequence is followed and each of the heat treating portions are started up sequentially, one at a time.

In the heating device disclosed in JP '743, in order to prevent electric power damage due to an excessive consumption current at the time of starting up the equipment, first the electric power that is necessary for the heater that is positioned below a conveyor is provided, and the electric power that is applied to heaters that are positioned above the conveyor is controlled in order to control the total quantity of electrical power consumed so as to be below a specific value, and as the temperature within the furnace increases, the temperature is used as a switching parameter, to perform control so as to reduce the quantity of electrical power supplied to the heaters that are positioned below the conveyor.

The technologies disclosed in JP '047, JP '743, JP '412, and Japanese Patent 4426155 each apply only when increasing the temperature through heating. In manufacturing equipment, the startup status is only an extremely limited time interval of the total operating time of the equipment, and, conversely, it is the time band that is termed the “steady-state,” wherein the control status is one wherein the controlled quantity PV (for example, temperature) is maintained at a constant quantity, that is overwhelmingly long. For example, in ventilation airflow control wherein the number of microbes or toxic substances in the air is measured and air exchange is performed to keep the number of microbes or toxic substances below a specified level, a fan is driven to maintain a stabilize state. In this case, increasing the speed of rotation of the fan beyond that which is necessary could lead to problems with the amount of energy used in the operating state that corresponds to the steady-state.

Consequently, there is the need to properly limit energy (and, in particular, to limit electric power) in the steady state. Because control calculations, for PID control, for example, are performed even in the steady state, it is necessary to limit the energy (limit the electric power) while considering the impact on control performance.

The present invention was created in order to solve the problems set forth above, and the object is to provide a total energy limiting and controlling device and total electric power limiting and controlling device and method able to perform control so that the quantity of energy used (for example, the quantity of electrical power used) in a steady state does not exceed a prescribed value that has been specified, and so that, insofar as is possible, external noise limiting performance is not lost.

### SUMMARY OF THE INVENTION

A total energy limiting and controlling device according to the present invention comprises: total allocated energy inputting means for receiving total allocated energy information that specifies a quantity of energy used for a control actuator of a plurality of controlled loops Ri (i=1 through n); energy value obtaining means for obtaining an energy consumption value for each controlled loop Ri; energy limiting means for calculating energy surplus of each controlled loop Ri from the energy consumption values and for calculating an operating quantity output upper limit value OHi for each controlled loop Ri based on the ratio of the energy surplus of each controlled loop Ri relative to the total energy surplus and on the total allocated energy; and controlling means for calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri; wherein: the operating quantity output upper limit value OHi is calculated so that the energy surpluses of the individual controlled loops Ri will approach a state of equality.

Moreover, a total electric power limiting and controlling device according to the present invention has total allocated electric power inputting means for receiving total allocated electric power PW information that specifies a quantity of electric power used for a control actuator of a plurality of controlled loops Ri (i=1 through n); electric power value obtaining means for obtaining an electric power consumption value CTi for each controlled loop Ri; electric power limiting means for calculating electric power surplus of each controlled loop Ri from the electric power consumption values CTi and for calculating an operating quantity output upper limit value OHi for each controlled loop Ri based on the ratio of the electric power surplus of each controlled loop Ri relative to the total electric power surplus and on the total allocated electric power PW; and controlling means for calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri; wherein: the operating quantity output upper limit value OHi is calculated so that the electric power surpluses of the individual controlled loops Ri will approach a state of equality.

Moreover, a total electric power limiting and controlling device according to the present invention includes total allocated electric power inputting means for receiving total allocated electric power PW information that specifies a quantity of electric power used for a control actuator of a plurality of controlled loops Ri (i=1 through n); electric power value obtaining means for obtaining an electric power consumption value CTi for each controlled loop Ri; maximum output electric power value obtaining means for obtaining a maximum output electric power consumption value CTmi for each controlled loop Ri; electric power surplus calculating means for calculating an electric power surplus CTri for each controlled loop Ri from the maximum output electric power consumption values CTmi and the electric power consumption values CTi; maximum total electric power calculating means for calculating a maximum total electric power BX, which is a sum of the maximum output electric power consumption values CTmi of the individual controlled loops Ri; total electric power surplus calculating means for calculating a total electric power surplus RW that is a sum of the electric power surpluses CTri of the individual controlled loops Ri; total electric power consumption calculating means for calculating a total electric power consumption SW, which is the total electric power quantity that should be consumed, from the maximum total electric power BX and the total allocated electric power PW; electric power consumption allocated quantity calculating means for calculating, from the electric power surpluses CTri, the total electric power surplus RW, and the total electric power consumption SW, an electric power consumption allocated quantity CTsi that is an electric power quantity that should be consumed by an individual controlled loop Ri; output upper limit calculating means for calculating an operating quantity output upper limit OHi for an individual controlled loop Ri from the electric power consumption allocated quantity CTsi and the maximum output electric power consumption value CTmi; and controlling means for calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri.

Moreover, a total electric power limiting and controlling device according to the present invention has total allocated electric power inputting means for receiving total allocated electric power PW information that specifies a quantity of electric power used for a control actuator of a plurality of controlled loops Ri (i=1 through n); electric power value obtaining means for obtaining an electric power consumption value CTi for each controlled loop Ri; maximum output electric power value obtaining means for obtaining a maximum output electric power consumption value CTmi for each controlled loop Ri; total electric power use calculating means for calculating a total electric power use QW that is a sum of the electric power consumption values CTi of the individual controlled loops Ri; electric power use allocated quantity calculating means for calculating, from the total allocated electric power PW, the electric power consumption values CTi, and the total electric power use QW, electric power use allocated quantities CTqi that are allocated to each of the controlled loops Ri; output upper limit calculating means for calculating an operating quantity output upper limit OHi for an individual controlled loop Ri from the maximum output electric power consumption value CTmi and the electric power use allocated quantity CTqi; and controlling means for calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri.

Moreover, a total energy limiting and controlling method according to the present invention includes an allocated total energy inputting step for receiving allocated total energy information that specifies a quantity of energy used for a control actuator of a plurality of controlled loops Ri (i=1 through n); an energy value obtaining step for obtaining an energy consumption value for each controlled loop Ri; an energy limiting step for calculating energy surplus of each controlled loop Ri from the energy consumption values and for calculating an operating quantity output upper limit value OHi for each controlled loop Ri based on the ratio of the energy surplus of each controlled loop Ri relative to the total energy surplus and on the total allocated energy; and a controlling step for calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri; wherein: the operating quantity output upper limit value OHi is calculated so that the energy surpluses of the individual controlled loops Ri will approach a state of equality.

Moreover, a total electric power limiting and controlling method according to the present invention has a total allocated electric power inputting step for receiving total allocated electric power PW information that specifies a quantity of electric power used for a control actuator of a plurality of controlled loops Ri (i=1 through n);

an electric power value obtaining step for obtaining an electric power consumption value CTi for each controlled loop Ri; an electric power limiting step for calculating electric power surplus of each controlled loop Ri from the electric power consumption values CTi and for calculating an operating quantity output upper limit value OHi for each controlled loop Ri based on the ratio of the electric power surplus of each controlled loop Ri relative to the total electric power surplus and on the total allocated electric power PW; and a controlling step for calculating an operating quantity MVi through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri; wherein: the operating quantity output upper limit value OHi is calculated so that the electric power surpluses of the individual controlled loops Ri will approach a state of equality.

Moreover, a total electric power limiting and controlling method according to the present invention has a total allocated electric power inputting step for receiving total allocated electric power PW information that specifies a quantity of electric power used for a control actuator of a plurality of controlled loops Ri (i=1 through n);

an electric power value obtaining step for obtaining an electric power consumption value CTi for each controlled loop Ri; a maximum output electric power value obtaining step for obtaining a maximum output electric power consumption value CTmi for each controlled loop Ri; an electric power surplus calculating step for calculating an electric power surplus CTri for each controlled loop Ri from the maximum output electric power consumption values CTmi and the electric power consumption values CTi; a maximum total electric power calculating step for calculating a maximum total electric power BX, which is the sum of the maximum output electric power consumption values CTmi of the individual controlled loops Ri; a total electric power surplus calculating step for calculating a total electric power surplus RW that is a sum of the electric power surpluses CTri of the individual controlled loops Ri; a total electric power consumption calculating step for calculating a total electric power consumption SW, which is the total electric power quantity that should be consumed, from the maximum total electric power BX and the total allocated electric power PW; an electric power consumption allocated quantity calculating step for calculating, from the electric power surpluses CTri, the total electric power surplus RW, and the total electric power consumption SW, an electric power consumption allocated quantity CTsi that is an electric power quantity that should be consumed by an individual controlled loop Ri; an output upper limit calculating step for calculating an operating quantity output upper limit OHi for an individual controlled loop Ri from the electric power consumption allocated quantity CTsi and the maximum output electric power consumption value CTmi; and a controlling step for calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri.

Moreover, a total electric power limiting and controlling method according to the present invention includes a total allocated electric power inputting step for receiving total allocated electric power PW information that specifies a quantity of electric power used for a control actuator of a plurality of controlled loops Ri (i=1 through n);

an electric power value obtaining step for obtaining an electric power consumption value CTi for each controlled loop Ri; a maximum output electric power value obtaining step for obtaining a maximum output electric power consumption value CTmi for each controlled loop Ri; a total electric power use calculating step for calculating a total electric power use QW that is a sum of the electric power consumption values CTi of the individual controlled loops Ri; an electric power use allocated quantity calculating step for calculating, from the total allocated electric power PW, the electric power consumption values CTi, and the total electric power use QW, electric power use allocated quantities CTqi that are allocated to each of the controlled loops Ri; an output upper limit calculating step for calculating an operating quantity output upper limit OHi for an individual controlled loop Ri from the maximum output electric power consumption value CTmi and the electric power use allocated quantity CTqi; and a controlling step for calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri.

The present invention makes it possible to obtain energy consumption values for each controlled loop Ri, to calculate energy surpluses for each controlled loop Ri from the energy consumption values, and to calculate operating quantity output upper limit values OHi for each controlled loop Ri based on the ratio of the energy surplus for each controlled loop Ri, relative to the total energy surplus, and on the total allocated energy, to thereby calculate operating quantity upper limit values OHi so that the energy surpluses of the individual controlled loops Ri approach a state of equality, so as to perform control for a plurality of control systems so that, in a steady-state, the energy use will not exceed a total allocated energy and so that, insofar as is possible, external noise limiting performance is not lost.

Moreover, the present invention makes it possible to obtain electric power consumption values CTi for each controlled loop Ri, to calculate electric power surpluses for each controlled loop Ri from the electric power consumption values CTi, and to calculate operating quantity output upper limit values OHi for each controlled loop Ri based on the ratio of the electric power surplus for each controlled loop Ri, relative to the total electric power surplus, and on the total allocated electric power PW, to thereby calculate operating quantity upper limit values OHi so that the electric power surpluses of the individual controlled loops Ri approach a state of equality, so as to perform control for a plurality of control systems so that, in a steady-state, the electric power use will not exceed a total allocated electric power PW and so that, insofar as is possible, external noise limiting performance is not lost.

### BRIEF DESCRIPTION OF THE DRAWINGS

FIG. 1 is a block diagram illustrating a structure of a heating device according to an example according to the present invention.

FIG. 2 is a block diagram illustrating a structure of a total electric power limiting/controlling device according to the example.

FIG. 3 is a block line diagram illustrating a structure of a controlling system according to the example of the present invention.

FIG. 4 is a flowchart illustrating the operation of the total electric power limiting/controlling device according to the example.

FIG. 5 is a diagram illustrating an operating example of a conventional heating device.

FIG. 6 is a diagram illustrating an operating example of a heating device according to an example of the present invention.

FIG. 7 is a block diagram illustrating a structure of a total electric power limiting/controlling device according to another example of the present invention.

FIG. 8 is a flowchart illustrating the operation of the total electric power limiting/controlling device according to the other example of the present invention.

FIG. 9 is a block diagram illustrating a structure of a ventilating quantity controlling device according to a further example of the present invention.

FIG. 10 is a block diagram illustrating a structure of a total energy limiting/controlling device according to yet another example of the present invention.

FIG. 11 is a block diagram illustrating a structure of another total energy limiting/controlling device according to the other example of the present invention.

### DETAILED DESCRIPTION OF THE PRESENT INVENTION

A heating device is used as an example in the description. In many heating devices, the heater output when in a steady-state is about 20% of the rating. Here the “steady-state” refers to a state wherein the controlled quantity PV is controlled in the vicinity of a setting value SP, a state wherein a controlling function is used in order to limit external noises. Because the heater output in the steady-state goes to about 20% of the rating, it is easy to heat the electric power use within a rough total allocated electric power even when, for example, a 600 W heater, with a total of three heaters, namely a 100 W heater, a 200 W heater, and a 300 W heater, is used under a condition wherein the total allocated power is 300 W (50% of the total heater capacity), because 100 W×20%=20 W, 200 W×20%=40 W, and 300 W×30%=60 W, for a total of 120 W. Consequently, it is easy to think that it is sufficient to uniformly control the output upper limits of each of the heaters to 50%.

However, when there is a large temperature-reducing external noise, such as by loading an object to be heated into a region of the heating device wherein a specific heater is disposed, the need arises to restore the temperature by increasing the output of this particular heater alone. Even if, at this time, the 50% output (the operating quantity MV) is insufficient, it would not be possible to have an output that exceeds the 50%, because the output upper limits for each of the heaters have been set uniformly to 50%. On the other hand, there will also be those heaters wherein there is surplus capacity because the output (the operating quantity MV) is 20% when the output upper limit is 50%. There will be heaters wherein, in the steady-state, the output (the operating quantity MV) will be about 10%, due to the effects of the radiant state, or the like, even when there are no external noises, and also heaters wherein the output (the operating quantity MV) will be about 30%. In these cases as well, if the output upper limits are uniformly 50%, there will be differences in the surplus electric power.

Consequently, if the electric powers used by the heaters in each of the controlled loops were measured or estimated to update the output upper limit values of appropriate control algorithms so that the electric power surpluses of the individual controlled loops were to approach a state of equality, then it would be possible to reduce the negative impact on the controllability in terms of limiting the external noises. Specifically, the difference between the total allocated power and the maximum total power, as the total amount of consumption, should be calculated, and each of the output upper limit values should be back-calculated so that the electric power surpluses will approach a state of equality given the relationships with the individual outputs (the operating quantities MV) at the current point in time.

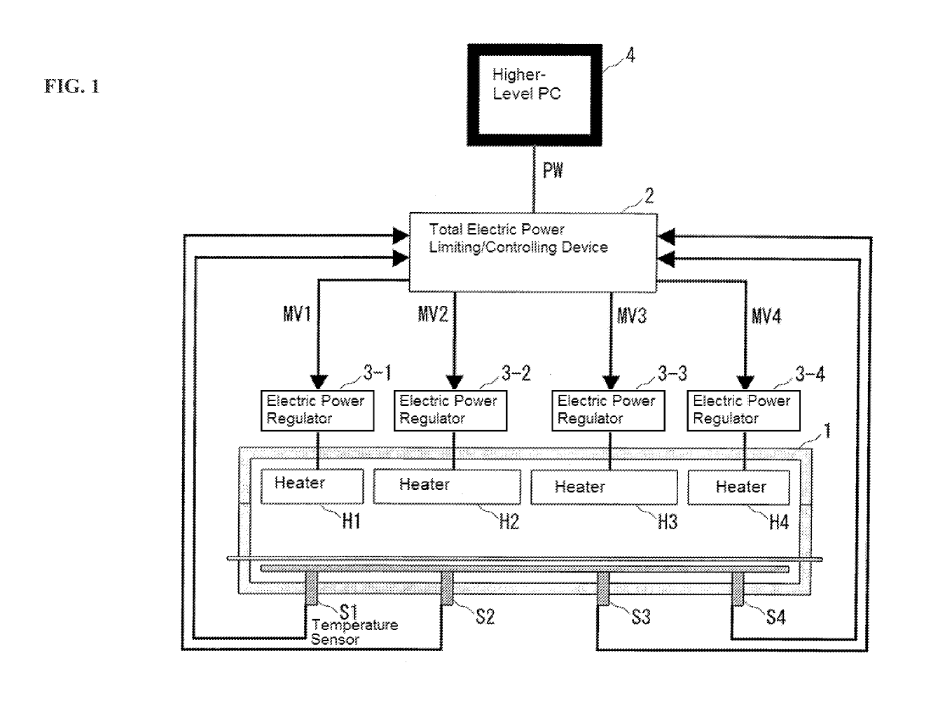

Examples carrying out the present invention are explained below in reference to the figures. FIG. 1 is a block diagram illustrating a structure of a heating device according to an example of the present invention. The heating device includes a heat treatment furnace 1 for heating an object to be heated; heaters H1 through H4, which are a plurality of control actuators disposed within the heat treatment furnace 1; a plurality of temperature sensors S1 through S4 that measure the temperatures of regions that are heated by the respective heaters H1 through H4; a total electric power limiting/controlling device 2 for calculating the operating quantities MV1 through MV4 from the outputs of the heaters H1 through the H4; and electric power regulators 3-1 through 3-4, for providing to the respective heaters H1 through H4, electric power in accordance with the operating quantities MV1 through MV4 that are outputted from the total electric power limiting/controlling device 2.

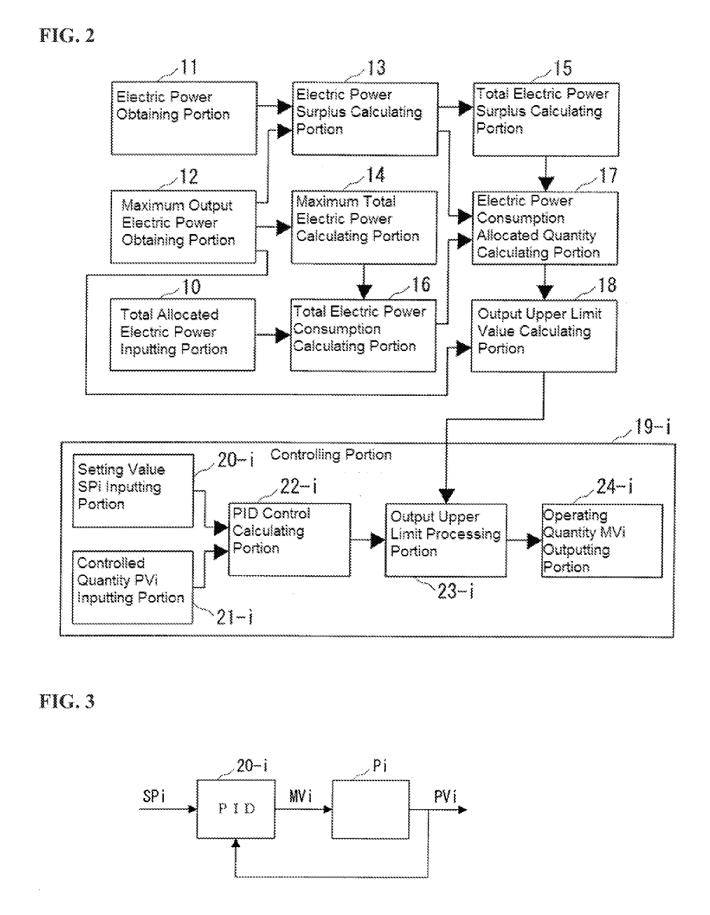

FIG. 2 is a block diagram illustrating the structure of the total electric power limiting/controlling device 2. The total electric power limiting/controlling device 2 is structured from: a total allocated electric power inputting portion 10 for receiving, from a higher-level PC 4, information regarding the total allocated electric power PW; an electric power value obtaining portion 11 for obtaining an electric power consumption value CTi for each of the controlled loops Ri (where i is between 1 and n, where the number n of controlled loops in the example in FIG. 1 is n=4); a maximum output electric power value obtaining portion 12 for obtaining a maximum output electric power consumption value CTmi for each controlled loop Ri; an electric power surplus calculating portion 13 for calculating an electric power surplus CTri for each controlled loop Ri from the maximum output electric power consumption value CTmi and the electric power consumption value CTi; a maximum total electric power calculating portion 14 for calculating a maximum total electric power BX that is the sum of the maximum output electric power consumption values CTmi of the individual controlled loops Ri; a total electric power surplus calculating portion 15 for calculating a total electric power surplus RW, which is the sum of the electric power surpluses CTri of the individual controlled loops Ri; a total electric power consumption calculating portion 16 for calculating, from the maximum total electric power BX and the total allocated electric power PW, a total electric power consumption SW, which is the total electric power quantity that should be consumed; an electric power consumption allocated quantity calculating portion 17 for calculating an electric power consumption allocated quantity CTsi that is the quantity of electric power that should be consumed, for each individual controlled loop Ri; an output upper limit value calculating portion 18 for calculating an operating quantity output upper limit value OHi for each individual controlled loop Ri from the electric power consumption allocated quantity CTsi and the maximum output electric power consumption value CTmi; and a controlling portion 19-i that is provided for each controlled loop Ri.

The maximum output electric power value obtaining portion 12, the electric power surplus calculating portion 13, the maximum total electric power calculating portion 14, the total electric power surplus calculating portion 15, the total electric power consumption calculating portion 16, the electric power consumption allocated quantity calculating portion 17, and the output upper limit value calculating portion 18 structure electric power controlling means. The controlling portion 19-i comprises a setting value SPi inputting portion 20-i; a controlled quantity PVi inputting portion 21-i, a PID control calculating portion 22-i; an output upper limit processing portion 23-i; and an operating quantity MVi outputting portion 24-i.

FIG. 3 is a block line diagram of a controlling system according to the example. Each controlled loop Ri is structured from a controlling portion 19-i and a controlled object Pi. As will be described below, the controlling portion 19-i calculates the operating quantity MVi from the setting value SPi and the controlled quantity PVi, and outputs that operating quantity MVi to the controlled object Pi. In the example in FIG. 1 the controlled object Pi is a heat treatment furnace 1 that is heated by a heater Hi; however, the actual output destination for the operating quantity MVi is the electric power adjusting device 3-i, where electric power commensurate with the operating quantity MVi is outputted from the electric power adjusting device 3-i to the heater Hi.

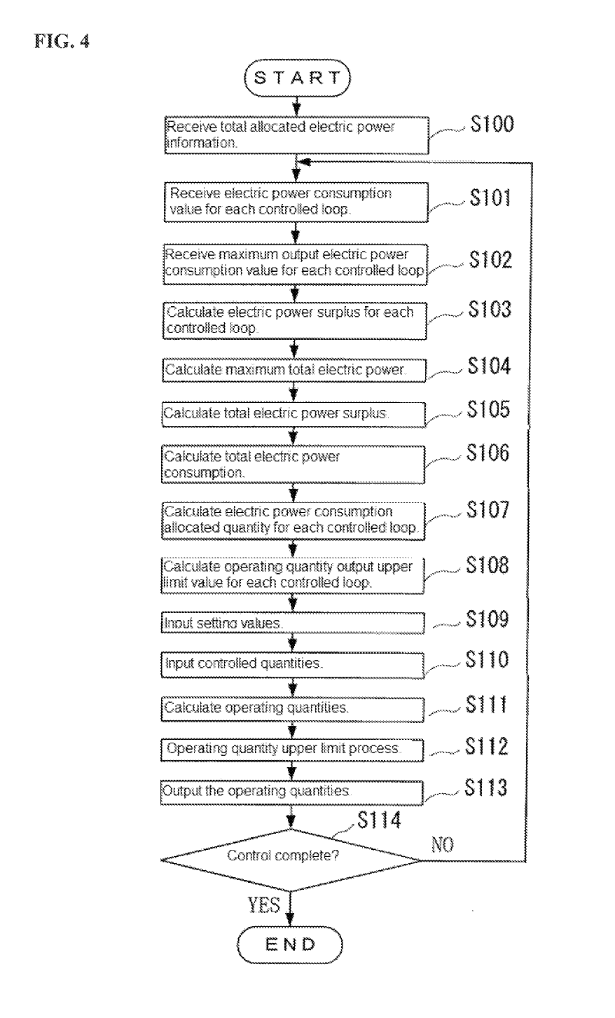

The operation of the total electric power limiting/controlling device 2 according to the example is explained below. FIG. 4 is a flowchart illustrating the operation of the total electric power limiting/controlling device 2. The total allocated electric power inputting portion 10 receives, from the higher-level PC 4, which is a computer of an electric power demand controlling system for controlling electric power, information pertaining to the total allocated electric power PW that specifies the quantities of electric power used by the heaters (Step S100 in FIG. 4).

The electric power value obtaining portion 11 obtains the current electric power consumption value CTi (specifically, the electric power consumption value for a heater Hi) for each controlled loop Ri (Step S101). The electric power value obtaining portion 11 may either measure or estimate the electric power consumption value CTi. The electric power consumption value CTi may be found through an electric power estimating function that is established in advance, with the value of the electric current that flows in the heater Hi and the controlled quantity PVi as input variables for estimating the electric power consumption value CTi. Moreover, the operating quantity MVi and the controlled quantity PVi may be used as input variables, or the value of the electric current that flows in the heater Hi, the controlled quantity PVi, and the operating quantity MVi may be used as input variables. A specific method for estimating the electric power consumption value CTi is disclosed in Japanese Unexamined Patent Application Publication 2009-229382, and thus detailed explanations thereof are omitted.

Following this, the maximum output electric power value obtaining portion 12 obtains the maximum output electric power consumption value CTmi for each controlled loop Ri (Step S102). Here the “maximum output” refers to when the operating quantity MVi is at the maximum value of 100%. The maximum output electric power value obtaining portion 12 may obtain a maximum output electric power consumption value CTmi that is stored in advance, or may estimate it. In estimating the maximum output electric power consumption value CTmi, the estimation may be approximated through the following equation, based on the electric power consumption value CTi and the operating quantity MVi that is outputted from the controlling portion 19-i:

CTmi=CTi(100.0/MVi) (1)

The electric power surplus calculating portion 13 uses the following equation to calculate, for each controlled loop Ri, an electric power surplus CTri for the individual controlled loop Ri (Step S103):

CTri=CTmi−CTi (2)

The maximum total electric power calculating portion 14 uses the following equation to calculate the maximum total electric power BX, which is the sum of the maximum output electric power consumption values CTmi for each of the controlled loops Ri (Step S104):

BX=ΣCTmi=CTm1+CTm2+ . . . +CTmn (3)

The total electric power surplus calculating portion 15 uses the following equation to calculate the total electric power surplus RW, which is the sum of the electric power surpluses CTri for each of the controlled loops Ri (Step S105):

RW=ΣCTri=CTr1+CTr2+ . . . +CTrn (4)

The total electric power consumption calculating portion 16 uses the following equation to calculate, from the maximum total electric power BX and the total allocated electric power PW, the total electric power consumption SW, which is the total amount of electric power that should be consumed (Step S106):

SW=BX−PW (5)

The electric power consumption allocated quantity calculating portion 17 uses the following equation to calculate, for each controlled loop Ri, and electric power consumption allocated quantity CTsi, which is the amount of electric power that should be consumed by the individual controlled loop Ri (Step S107):

CTsi=SW(CTri/RW) (6)

The output upper limit value calculating portion 18 uses the following equation to calculate, for each controlled loop Ri, an operating quantity output upper limit value OHi for each individual controlled loop Ri, from the electric power consumption allocated quantity CTsi and the maximum output electric power consumption value CTmi (Step S108):

OHi={1.0−(CTsi/CTmi)}100.0% (7)

Note that if BX<PW, that is, if SW<0, then OHi would exceed 100%, in which case the OHi should be clipped with an upper limit at 100%.

Following this, the controlling portion 19-i calculates the operating quantity MVi for the controlled loop Ri as shown below. The setting value SPi is set by a user of the heating device, and is inputted into the PID control calculating portion 22-i through the setting value SPi inputting portion 20-i (Step S109). The controlled quantity PVi (the temperature) is measured by a temperature sensor Si, and is inputted into the PID control calculating portion 22-i through the controlled quantity PVi inputting portion 21-i (Step S110).

The PID control calculating portion 22-i calculates the operating quantity MVi by performing the PID control calculations as per the following transfer function based on the setting value SPi and the controlled quantity PVi (Step S111):

MVi=(100/PBi){1+(1/TIis)+TDis}(SPi−PVi) (8)

PBi is a proportionality band, TIi is an integrating time, TDi is a differentiating time, and s is the Laplace operator.

The output upper limit processing portion 23-i performs an upper limit process on the operating quantity MVi as per the following equation (Step S112):

If MVi>OHi then MVi=OHi (9)

That is, the output upper limit processing portion 23-i performs an upper limit process to make the operating quantity MVi=OHi if the operating quantity MVi is greater than the operating quantity output upper limit value OHi.

The operating quantity MVi output portion 24-i outputs to the controlled object (where the actual output destination is the electric power adjusting device 3-i) the operating quantity MVi that has been subjected to the upper limit processing by the output upper limit processing portion 23-i (Step S113). A controlling portion 19-i is provided for each individual controlled loop Ri, so the processes in Step S109 through S113 are executed for each controlled loop Ri. The total electric power limiting/controlling device 2 performs the processes in Step S101 through S113, as described above, at predetermined intervals until, for example, control is terminated by a user instruction (Step S114: YES).

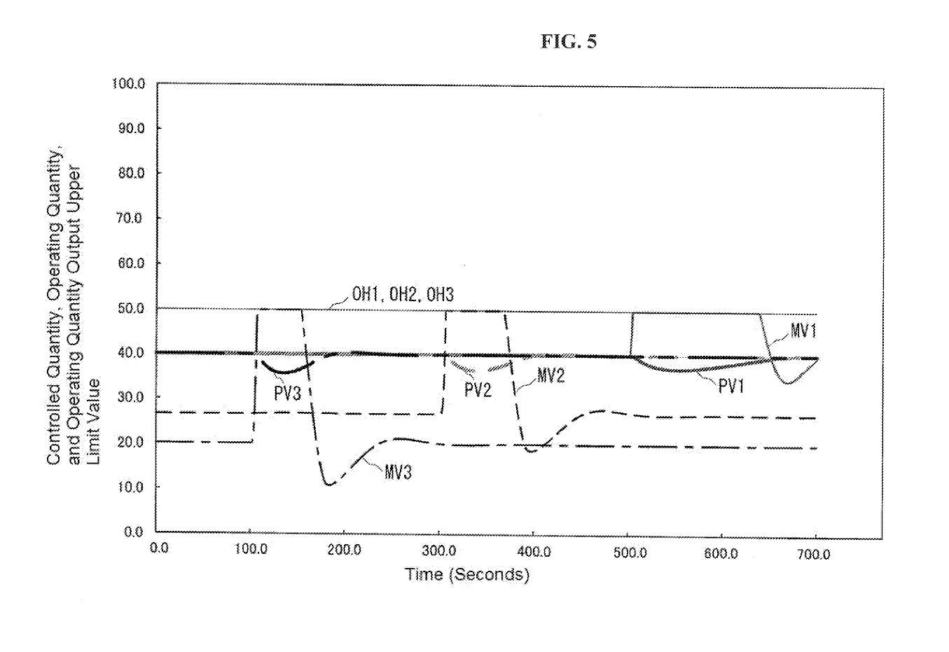

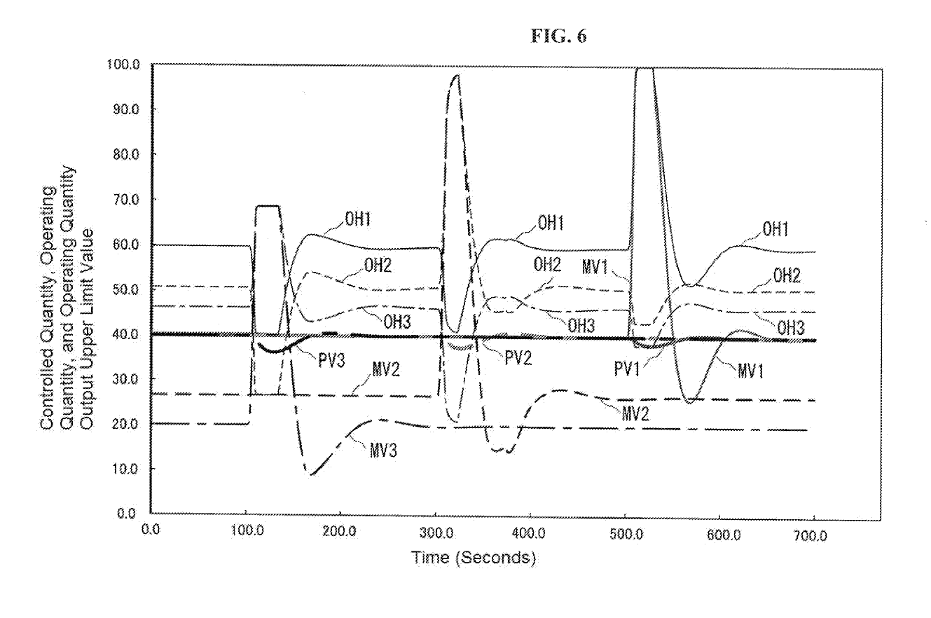

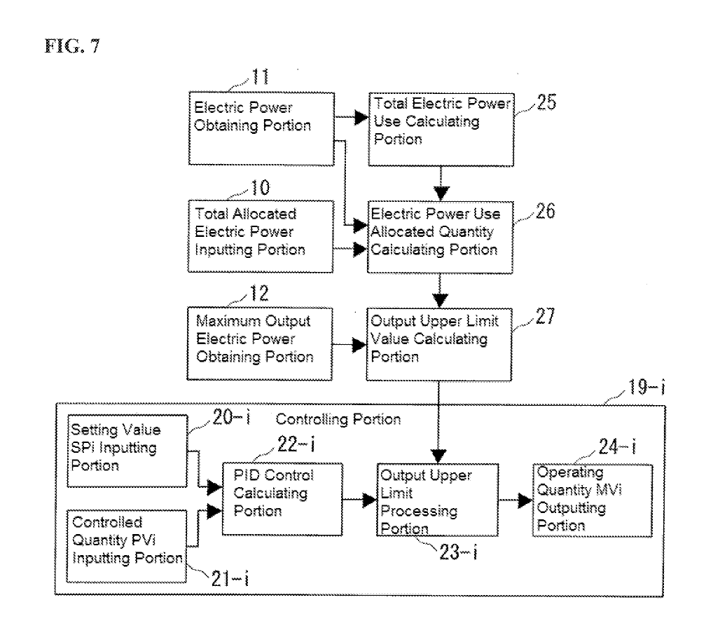

An example of operation of the heating device according to the present example is shown next in FIG. 5 and FIG. 6. In consideration of ease in understanding, an operating example of a controlling system wherein n=3 loops is shown in FIG. 5 and FIG. 6. FIG. 5 shows an example of operation of a conventional heating device wherein control is performed with the output upper limit for each heater set uniformly to 50% in a situation wherein, for a 600 W heater, with a total of three individual heaters, heater H1 at 100 W, heater H2 at 200 W, and heater H3 at 300 W, with a total allocated electric power PW of 300 W (50% of the total heater capacity). The vertical axes show the controlled quantity PVi, the operating quantity MVi, and the operating quantity output upper limit value OHi, each shown on a 0-100 scale. The units for the controlled quantity PVi are ° C., and the units for the operating quantity MVi and the operating quantity output upper limit value OHi are percentages.

In the example in FIG. 5, the setting value SPi=40° C., and so the controlled quantity PVi (the temperature) is controlled so as to maintain 40.0° C.; however, after temperature-reducing external noises are applied at times 100.0 seconds, 300.0 seconds, and 500.0 seconds to the respective controlled quantities PV3, PV2, and PV1, the controlled quantities PV3, PV2, and PV1 are restored to 40.0° C. through external noise limiting control by the controlling portions 19-i. It can be seen that in any of the controlled loops, when a temperature-reducing external noise is applied, the operating quantity MVi is limited to the output upper limit value OHi=50%, sacrificing the control performance.

FIG. 6 shows an example of operation of a heating device according to the present example under these same conditions. In the present example, the output upper limits of the individual heaters are not uniformly 50%, and the operating quantity output upper limit values OHi are set to values in accordance with the electric power surpluses even when in a state wherein no external noises are applied, so when an external noise is applied and the operating quantity MVi increases, the electric power surplus is reduced, and the operating quantity output upper limit value OHi also increases in accordance therewith, and the operating quantity output upper limit values OHi of the controlled loops wherein no external noises are applied are reduced by a commensurate amount. Doing so makes it possible to achieve, in the present example, control operations wherein the controllability of the external noise limiting control does not suffer greatly when compared to the case in FIG. 5.

In addition, in the present example the operating quantity MV1 is not changed directly, but rather the operating quantity output upper limit value OH1 is changed, so no extraneous variation is produced in the operating quantity MV1. That is, this makes it possible to obtain a control-response waveform that is not unnatural, adversely affecting the PID control calculations.

Moreover, in the present example the electric power surpluses are calculated rigorously when calculating the operating quantity output upper limit values OHi, thus making it possible to monitor and control the electric power surpluses through the provision of indicating means for indicating, to the user, the electric power surpluses CTri for each of the controlled loops Ri or the total electric power surplus RW, which is the sum thereof.

Note that the processing sequence in the total electric power limiting/controlling device 2 in the present invention need not, of course, be as illustrated in FIG. 4. Moreover, while in the example in FIG. 4 the total allocated electric power PW information was received only once, the higher-level PC 4 may send information as necessary, and the values for the total allocated electric power PW may be updated constantly thereby.

Another example according to the present invention is explained next. While in the present example, the electric power surplus is not calculated rigorously when calculating the operating quantity output upper limit values OHi, the operating quantity output upper limit values are calculated so that the electric power surpluses essentially approach a state of equality. Doing so makes it possible to achieve essentially the same effects as in the above example.

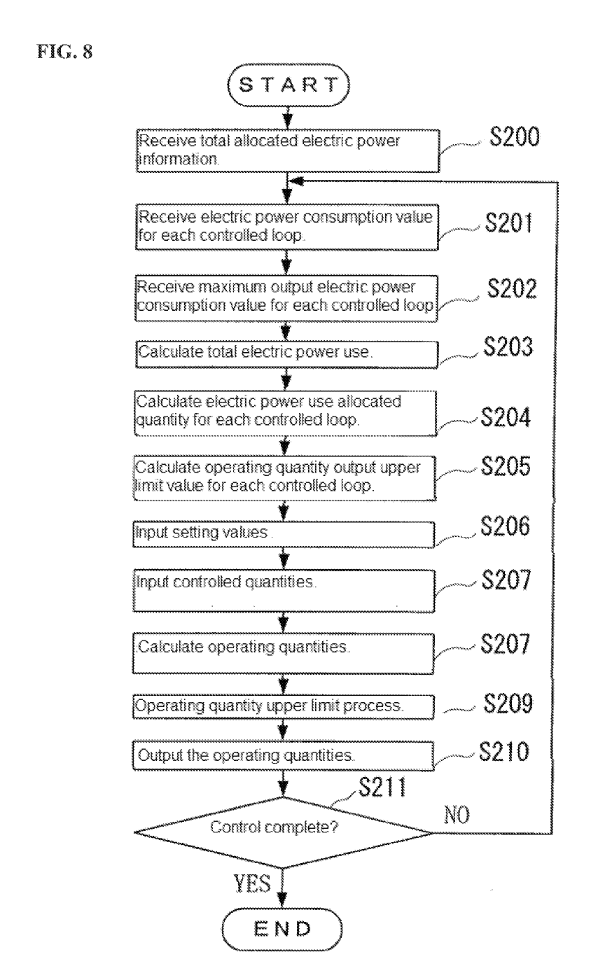

In the present example as well, the structure of the heating device in its entirety is identical to that in the above example, and thus the codes in FIG. 1 is used in the explanation. FIG. 7 is a block diagram illustrating one configuration of a total electric power limiting/controlling device 2 according to the present example. The total electric power limiting/controlling device 2 according to the present example is structured from: a total allocated electric power inputting portion 10 for receiving, from a higher-level PC 4, information regarding the total allocated electric power PW; an electric power value obtaining portion 11 for obtaining an electric power consumption value CTi for each of the controlled loops Ri (where i is between 1 and n; a maximum output electric power value obtaining portion 12 for obtaining a maximum output electric power consumption value CTmi for each controlled loop Ri; a controlling portion 19-i that is provided for each controlled loop Ri; a total electric power use calculating portion 25 for outputting a total electric power use QW, which is the sum of the electric power consumption values CTi for the individual controlled loops Ri; an electric power use allocated quantity calculating portion 26 for calculating, from the total allocated electric power PW, the electric power consumption values CTi of the individual controlled loops Ri, and the total electric power use QW, the electric power use allocated quantities CTqi that are allocated to the individual controlled loops Ri; and an output upper limit value calculating portion 27 for calculating an operating quantity output upper limit value OHi for each of the controlled loops Ri from the maximum output electric power consumption values CTmi and the electric power use allocated quantities CTqi of the individual controlled loops Ri. The maximum output electric power value obtaining portion 12, the total electric power use calculating portion 25, the electric power use allocated quantity calculating portion 26, and the output upper limit value calculating portion 27 structure electric power limiting means. The structure of the controlling portion 19-i is identical to that in the above example.

The operation of the total electric power limiting/controlling device 2 according to the present example is explained below. FIG. 8 is a flowchart illustrating the operation of the total electric power limiting/controlling device 2. The processes in Steps S200, S201, and S202 in FIG. 8 are identical to those in the respective Steps S100, S101, and S102 in FIG. 4, so explanations thereof are omitted.

The total electric power use calculating portion 25 uses the following equation to calculate the total electric power use QW, which is the sum of the electric power consumption values CTi for each of the controlled loops Ri (Step S203 in FIG. 8):

QW=ΣCTi=CT1+CT2+ . . . +CTn (10)

The electric power use allocated quantity calculating portion 46 uses the following equation to calculate, for each controlled loop Ri, the electric power use allocated quantities CTqi that are allocated to the individual controlled loops Ri, from the total allocated electric power PW, the electric power consumption values CTi of the individual controlled loops Ri, and the total electric power use QW (Step S204):

CTqi=PW(CTi/QW) (11)

The output upper limit value calculating portion 27 uses the following equation to calculate the operating quantity output upper limit value OHi for each individual controlled loop Ri, from the maximum output electric power consumption value CTmi and the electric power use allocated quantity CTqi for each of the controlled loops Ri (Step S205): The meaning of Equation 13 is that OHi will be set to 100% if the operating quantity output upper limit value OHi calculated by equation (12) is larger than 100%.

OHi=(CTqi/CTmi)100.0% (12)

If OHi>100.0% then OHi=100.0% (13)

Steps S206, S207, S208, S209, and S210 in FIG. 8 are identical to the respective steps S109, S110, S111, S112, and S113 in FIG. 4, and thus explanations thereof are omitted. The total electric power limiting/controlling device 2 performs the processes in Step S201 through S210, as described above, at regular time intervals until, for example, the control is terminated through a user instruction (Step S211: YES). Identical effects as in the above example can be obtained through the present example as well.

Note that while a heating device was used as an example in the explanations in the above example, the present invention may instead be applied, for example, to cooling equipment for controlling the cooling temperature of an object or to a ventilating quantity controlling device for controlling the amount of ventilation of a controlled space. In hygienic facilities such as foodstuff factories, pharmaceutical product factories, hospitals, or the like, there is a problem in that there is the potential for incursion of airborne bacteria or adhesive bacteria into the room accompanying entry and exit of people and objects, where the adhesion and the growth of airborne bacteria and adhesive bacteria on wall surfaces or devices within the room may cause the room to become contaminated. The room becoming contaminated is a problem that may lead to decreased product quality, or, in the case of a foodstuff, food poisoning. Conventionally this problem has often been handled through the use of a method wherein circulating air has been filtered through an air purifying filter before being blown into the room. The ventilation quantity controlling device is that which is used in order to filter and ventilate such air into a room. A ventilation quantity controlling device is disclosed in, for example, Japanese Unexamined Patent Application Publication 2005-106296.

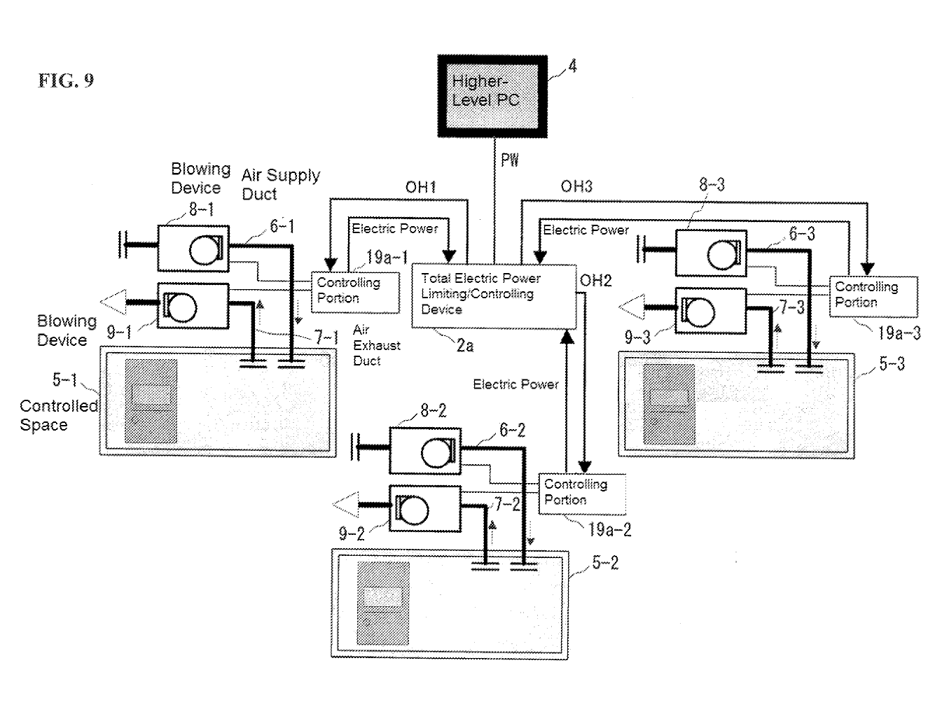

FIG. 9 is a block diagram illustrating a structure of a ventilation quantity controlling device according to the present example. The ventilation quantity controlling device is structured from: a total electric power limiting/controlling device 2a, air supplying ducts 6-1 through 6-3 for supplying air into controlled spaces 5-1 through 5-3; air exhaust ducts 7-1 through 7-3 for exhausting the air of the controlled spaces 5-1 through 5-3; blowing devices 8-1 through 8-3, which are control actuators for supplying the supply air; blowing devices 9-1 through 9-3 which are control actuators for performing the air exhaust; and controlling portions 19a-1 through 19a-3.

The structure of the total electric power limiting/controlling device 2a is basically the same as that of the total electric power limiting/controlling device 2 in the above example. However, the difference between the above examples is in the provision of the controlling portions 19a-1 through 19a-3 on the outside of the total electric power limiting/controlling device 2a. The controlling portions 19a-i (where i=1 through n, where n=3 in the example in FIG. 9) has detecting means for detecting the electric power consumption of the blowing devices 8-i and 9-i. Each of the air supplying ducts 6-1 through 6-3 is provided with an air cleaning filter (not shown).

When air exchange is performed through blowing into the controlled space air that has been filtered by an air cleaning filter, this consumes the transporting power of the blowing device. Conventionally, the reliable elimination of bacteria has been the priority, so operations have been performed with the airflow set on the high side so as to have a sufficient margin. In this case, even if the bacteria were actually reduced adequately, still the operation would have the high air flow, essentially resulting in waste of the transporting power.

Given this, the number of microbes in the controlled space 5-i is counted in real time as the controlled quantity PVi, and the electric power used in ventilation can be limited through limiting the speed of rotation of the fans of the blowing devices 8-i and 9-i, with the ventilating quantities as the operating quantities MVi. The present invention is applicable insofar as there is a plurality of the controlled loops, as illustrated in FIG. 9. The bacteria are measured through the Instantaneous Microbe Detector, developed by BioVigilant Systems in the United States (Norio Hasegawa, et al., “Instantaneous Bioaerosol Detection Technology and Its Application,” Yamatake Company, Ltd., azbil Technical Review, December 2009, pg. 2-7, 2009). Identical effects as in the first form of embodiment can be obtained through the ventilating quantity controlling device as well. While in the above examples the operating quantity output upper limit value OHi was calculated based on an electric power quantity, there is no limitation thereto, and instead the calculation may be based on a fuel use. That is, in the present invention, a form wherein the physical quantity known as “electric power,” which was used in the total electric power limiting/controlling devices 2 and 2a in the first through third forms of embodiment is replaced with “energy” or “power.”

The structure of a total energy limiting/controlling device wherein the physical quantity known as “electric power” that was used in the total electric power limiting/controlling device 2 in the first form of embodiment has been replaced with “energy,” and the structure of a total energy limiting/controlling device wherein the physical quantity known as “electric power” that was used in the total electric power limiting/controlling device 2 in one of the above examples has been replaced with “energy.”

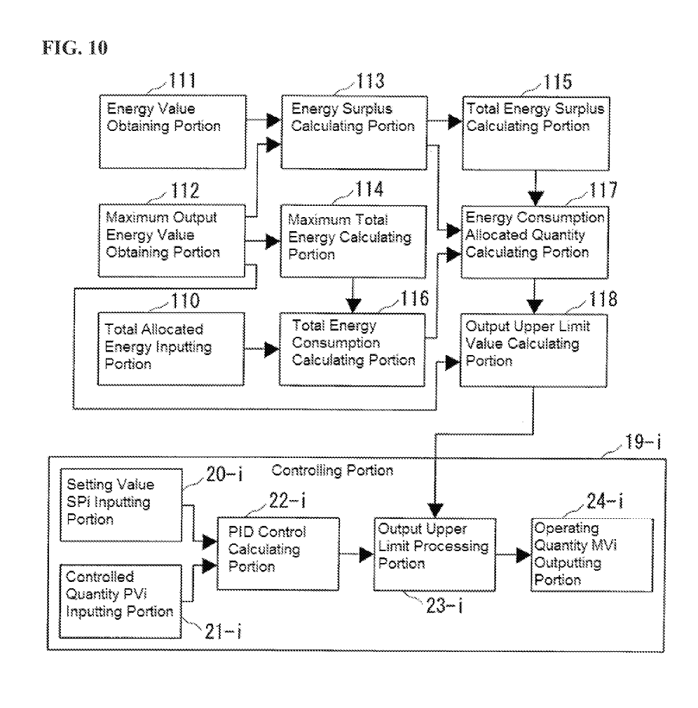

The total energy limiting/controlling device in FIG. 10 is structured from: a total allocated energy inputting portion 110; an energy value obtaining portion 111; a maximum output energy value obtaining portion 112; an energy surplus calculating portion 113; a maximum total energy calculating portion 114; a total energy surplus calculating portion 115; a total energy consumption calculating portion 116; an energy consumption allocated quantity calculating portion 117; an output upper limit value calculating portion 118, and a controlling portion 19-i that is provided for each controlled loop Ri. The structure of this total energy limiting/controlling device corresponds to the replacement of the “electric power” in the above example with “energy,” and thus detailed explanations are omitted.

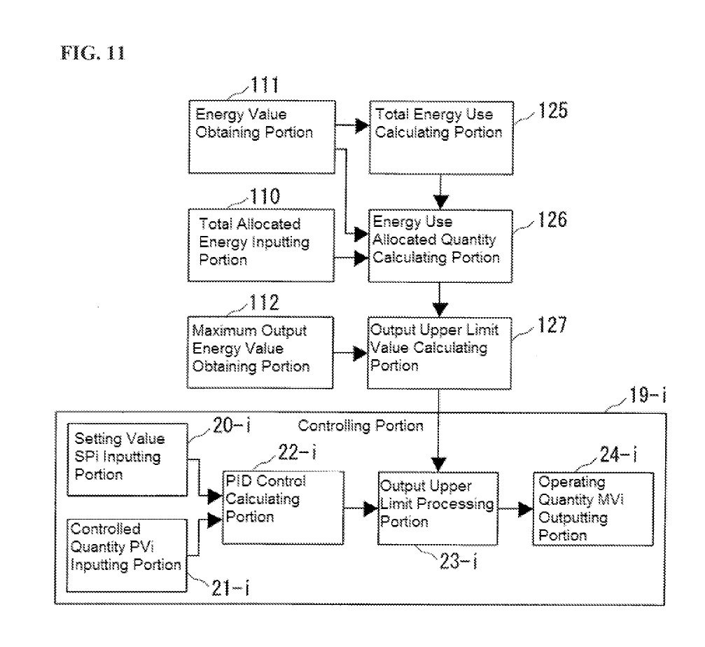

The total energy limiting/controlling device in FIG. 11 is structured from: a total allocated energy inputting portion 110; an energy value obtaining portion 111; a maximum output energy value obtaining portion 112; a total energy use calculating portion 125; an energy use allocated quantity calculating portion 126; an output upper limit value calculating portion 127; and a controlling portion 19-i that is provided for each controlled loop Ri. As with the case in FIG. 10, the structure of this total energy limiting/controlling device corresponds to the replacement of the “electric power” in the example with “energy,” and thus detailed explanations are omitted.

The total electric power limiting/controlling device and total energy limiting/controlling device explained in the examples may be embodied through a computer that is equipped with a CPU, a storage device, and an interface, combined with a program for controlling these hardware resources. The CPU executes the processes explained in the examples, in accordance with a program that is stored in the memory device.

The present invention can be applied to control devices and control methods for multiple control systems provided with a plurality of controlled loops.

1. A total energy limiting and controlling device comprising:
a total allocated energy inputting device receiving total allocated energy information that specifies a quantity of energy used for a control actuator of a plurality of controlled loops Ri (i=1 through n);
an energy value obtaining device obtaining an energy consumption value for each controlled loop Ri;
an energy limiting device calculating energy surplus of each controlled loop Ri from the energy consumption values and for calculating an operating quantity output upper limit value OHi for each controlled loop Ri based on the ratio of the energy surplus of each controlled loop Ri relative to the total energy surplus and on the total allocated energy; and
a controller calculating an operating quantity MVi, provided for each controlled loop Ri, through control calculations upon inputting of the setting value SPi and the control quantity PVi, for executing an upper limit process to limit the operating quantity MVI so as to be no higher than the operating quantity output upper limit value OHi, and for outputting the operating quantity MVi, after the upper limit process, to a control actuator of a corresponding controlled loop Ri; wherein:
the operating quantity output upper limit value OHi is calculated so that the energy surpluses of the individual controlled loops Ri will approach a state of equality.

2. A total electric power limiting and controlling device comprising:
a total allocated electric power inputting device receiving total allocated electric power PW information that specifies a quantity of electric power used for a control actuator of a plurality of controlled loops Ri (i=1 through n);
an electric power value obtaining device obtaining an electric power consumption value CTi for each controlled loop Ri;
an electric power limiter calculating electric power surplus of each controlled loop Ri from the electric power consumption values CTi and for calculating an operating quantity output upper limit value OHi for each controlled loop Ri based on the ratio of the electric power surplus of each controlled loop Ri relative to the total electric power surplus and on the total allocated electric power PW; and
a controller an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri; wherein:
the operating quantity output upper limit value OHi is calculated so that the electric power surpluses of the individual controlled loops Ri will approach a state of equality.

3. A total electric power limiting and controlling device comprising:
a total allocated electric power inputting device receiving total allocated electric power PW information that specifies a quantity of electric power used for a control actuator of a plurality of controlled loops Ri (i=1 through n);
an electric power value obtaining device obtaining an electric power consumption value CTi for each controlled loop Ri;
a maximum output electric power value obtaining device obtaining a maximum output electric power consumption value CTmi for each controlled loop Ri;
an electric power surplus calculator calculating an electric power surplus CTri for each controlled loop Ri from the maximum output electric power consumption values CTmi and the electric power consumption values CTi;
a maximum total electric power calculator calculating a maximum total electric power BX, which is the sum of the maximum output electric power consumption values CTmi of the individual controlled loops Ri;
a total electric power surplus calculator calculating a total electric power surplus RW that is a sum of the electric power surpluses CTri of the individual controlled loops Ri;
a total electric power consumption calculator calculating a total electric power consumption SW, which is the total electric power quantity that should be consumed, from the maximum total electric power BX and the total allocated electric power PW;
an electric power consumption allocated quantity calculator calculating, from the electric power surpluses CTri, the total electric power surplus RW, and the total electric power consumption SW, an electric power consumption allocated quantity CTsi that is an electric power quantity that should be consumed by an individual controlled loop Ri;
an output upper limit calculator calculating an operating quantity output upper limit OHi for an individual controlled loop Ri from the electric power consumption allocated quantity CTsi and the maximum output electric power consumption value CTmi; and
a controller calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri.

4. A total electric power limiting and controlling device comprising:
a total allocated electric power inputting device receiving total allocated electric power PW information that specifies a quantity of electric power used for a control actuator of a plurality of controlled loops Ri (i=1 through n);
an electric power value obtaining device obtaining an electric power consumption value CTi for each controlled loop Ri;
a maximum output electric power value obtaining device obtaining a maximum output electric power consumption value CTmi for each controlled loop Ri;
a total electric power use calculator calculating a total electric power use QW that is a sum of the electric power consumption values CTi of the individual controlled loops Ri;
an electric power use allocated quantity calculator calculating, from the total allocated electric power PW, the electric power consumption values CTi, and the total electric power use QW, electric power use allocated quantities CTqi that are allocated to each of the controlled loops Ri;
an output upper limit calculator calculating an operating quantity output upper limit OHi for an individual controlled loop Ri from the maximum output electric power consumption value CTmi and the electric power use allocated quantity CTqi; and
a controller calculating an operating quantity MVi, provided for each controlled loop Ri, through control calculations upon inputting of a setting value SPi and a control quantity PVi, for executing an upper limit process to limit the operating quantity MVi so as to be no higher than the operating quantity output upper limit value OHi, and for outputting the operating quantity MVi, after the upper limit process, to a control actuator of a corresponding controlled loop Ri.

5. A total energy limiting and controlling method comprising:
a total allocated energy inputting step receiving total allocated energy information that specifies a quantity of energy used for a control actuator of a plurality of controlled loops Ri (i=1 through n);
an energy value obtaining step obtaining an energy consumption value for each controlled loop Ri;
an energy limiting step calculating energy surplus of each controlled loop Ri from the energy consumption values and for calculating an operating quantity output upper limit value OHi for each controlled loop Ri based on the ratio of the energy surplus of each controlled loop Ri relative to the total energy surplus and on the total allocated energy; and
a controlling step calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri; wherein:
the operating quantity output upper limit value OHi is calculated so that the energy surpluses of the individual controlled loops Ri will approach a state of equality.

6. A total electric power limiting and controlling method comprising:
a total allocated electric power inputting step receiving total allocated electric power PW information that specifies a quantity of electric power used for a control actuator of a plurality of controlled loops Ri (i=1 through n);
an electric power value obtaining step obtaining an electric power consumption value CTi for each controlled loop Ri;
an electric power limiting step calculating electric power surplus of each controlled loop Ri from the electric power consumption values CTi and for calculating an operating quantity output upper limit value OHi for each controlled loop Ri based on the ratio of the electric power surplus of each controlled loop Ri relative to the total electric power surplus and on the total allocated electric power PW; and
a controlling step calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri; wherein:
the operating quantity output upper limit value OHi is calculated so that the electric power surpluses of the individual controlled loops Ri will approach a state of equality.

7. A total electric power limiting and controlling method comprising:
a total allocated electric power inputting step receiving total allocated electric power PW information that specifies a quantity of electric power used for a control actuator of a plurality of controlled loops Ri (i=1 through n);
an electric power value obtaining step obtaining an electric power consumption value CTi for each controlled loop Ri;
a maximum output electric power value obtaining step obtaining a maximum output electric power consumption value CTmi for each controlled loop Ri;
an electric power surplus calculating step calculating an electric power surplus CTri for each controlled loop Ri from the maximum output electric power consumption values CTmi and the electric power consumption values CTi;
a maximum total electric power calculating step calculating a maximum total electric power BX, which is the sum of the maximum output electric power consumption values CTmi of the individual controlled loops Ri;
a total electric power surplus calculating step calculating a total electric power surplus RW that is a sum of the electric power surpluses CTri of the individual controlled loops Ri;
a total electric power consumption calculating step calculating a total electric power consumption SW, which is the total electric power quantity that should be consumed, from the maximum total electric power BX and the total allocated electric power PW;
an electric power consumption allocated quantity calculating step calculating, from the electric power surpluses CTri, the total electric power surplus RW, and the total electric power consumption SW, an electric power consumption allocated quantity CTsi that is an electric power quantity that should be consumed by an individual controlled loop Ri;
an output upper limit calculating step calculating an operating quantity output upper limit OHi for an individual controlled loop Ri from the electric power consumption allocated quantity CTsi and the maximum output electric power consumption value CTmi; and
a controlling step calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri.

8. A total electric power limiting and controlling method comprising:
a total allocated electric power inputting step receiving total allocated electric power PW information that specifies a quantity of electric power used for a control actuator of a plurality of controlled loops Ri (i=1 through n);
an electric power value obtaining step obtaining an electric power consumption value CTi for each controlled loop Ri;
a maximum output electric power value obtaining step obtaining a maximum output electric power consumption value CTmi for each controlled loop Ri;
a total electric power use calculating step calculating a total electric power use QW that is a sum of the electric power consumption values CTi of the individual controlled loops Ri;
an electric power use allocated quantity calculating step calculating, from the total allocated electric power PW, the electric power consumption values CTi, and the total electric power use QW, electric power use allocated quantities CTqi that are allocated to each of the controlled loops Ri;
an output upper limit calculating step calculating an operating quantity output upper limit OHi for an individual controlled loop Ri from the maximum output electric power consumption value CTmi and the electric power use allocated quantity CTqi; and
a controlling step calculating an operating quantity MVi through control calculations upon inputting of the setting value SPi and the control quantity PVi, for executing an upper limit process to limit the operating quantity MVI so as to be no higher than the operating quantity output upper limit value OHi, and to output the operating quantity MVi, after the upper limit process, to a control actuator of a corresponding controlled loop Ri.
